(19) United States
(12) Patent Application Publication
(10) Pub. No.: US 2018/0364578 A1
(43) Pub. Date: Dec. 20, 2018

(54) LED-Based Ultraviolet illuminator

(71) Applicant: LITRO TECHNOLOGY CO., LTD, Hsinchu County (TW)

(72) Inventor: TE-LI HU, Hsinchu County (TW)

(21) Appl. No.: 16/012,596

(22) Filed: Jun. 19, 2018

(30) Foreign Application Priority Data
Jun. 19, 2017 (TW) 106120440

(51) Int. Cl. G03F 7/20

(52) U.S. Cl. CPC G03F 7/7005; G03F 7/70075; G03F 7/70558; G03F 7/7085; G03F 7/7015

(57) ABSTRACT

An LED-based ultraviolet illuminator includes an exposure module, an illumination module, a light mixing system, a beam splitter, an optical lens system, a sensor and a controller. The exposure module includes light sources that emit UV light at different wavelengths. The illumination module includes at least one light source that emits visible light for alignment. The sensor detects light energy of a portion of the UV light at each wavelength. The controller is operably connected to the exposure module and the sensor, and configured to operate in a plurality of exposure modes according to which the controller turns on or off the UV-LED light sources of the exposure module. The controller is further configured to adjust an output of the UV-LED light sources of the exposure module based on a detected result of the sensor.

### BACKGROUND OF THE INVENTION

### 1. Field of the Invention

The present invention relates to an illuminator for an exposure system, and more particularly to an LED-based ultraviolet illuminator.

### 2. Description of the Related Art

Conventional illuminators in ultraviolet-(UV-)wavelength lithography systems use mercury (Hg) lamps. Mercury lamps are typically used for UV wavelengths between about 360 and 450 nm. To increase the throughput of the lithography system, the lamp brightness needs to be increased. However, increasing the power in a mercury lamp usually comes at the cost of increasing the source size. For this and other reasons, the mercury lamp has been gradually replaced by a LED-based ultraviolet illuminator.

U.S. Patent Pub. No. 2010/0283978 discloses a UV illuminator that makes efficient use of UV light-emitting diode (LED) light sources to provide efficient light collection and high illumination output. More specifically, the LED-based UV illuminator uses one or more light homogenizers such as light pipes to integrate UV light emitted by multiple UV LED light sources in the form of LED arrays.

China Patent Pub. No 106054538 discloses an ultraviolet illuminator for an exposure system. The ultraviolet illuminator employs a plurality of light sources with different wavelengths, such as 365 nm, 385 nm, and 405 nm. In general, the light at wavelength of 405 nm is most stable and powerful in use, with less exposure time needed, but not many photosensitive ingredients are sensitive to that radiation. Rather, most of the photosensitive ingredients are suitable for the radiation at wavelengths of 365 nm or 385 nm, even though it is less stable and less powerful. The ultraviolet illuminator of this patent is dedicated to reduce or avoid the disadvantages which may occur in an illuminator of a single-wavelength light source, and improve the ultraviolet exposure efficiency by combining the advantages of the light sources with the different wavelengths.

However, in each case, no UV-LED illuminator can be controlled or optimized to achieve a desired output power; and no UV-LED illuminator can be controlled or adjusted precisely to provide mixed light in a desired mixing ratio for a particular photosensitive ingredient.

### SUMMARY OF THE INVENTION

Accordingly, it is an object of the present invention to provide a light-emitting diode-(LED)-based ultraviolet illuminator to satisfy the aforementioned need. The LED-based ultraviolet illuminator of this invention generally includes an exposure module, an illumination module, a light mixing system, a beam splitter, an optical lens system, a sensor and a controller.

Briefly described, the exposure module includes a plurality of UV-LED light sources that emit UV light at different wavelengths for activating a photosensitive layer. The illumination module includes at least one visible LED light source that emits visible light for alignment of a reticle with the photosensitive layer. The light mixing system is provided for receiving the UV light of the different wavelengths from the exposure module, and combining the UV light into a mixed light beam. The beam splitter is provided for splitting the mixed light beam into a primary light beam and a secondary light beam, each of which contains a portion of the UV light with all the different wavelengths. The optical lens system is provided for receiving the primary light beam from the beam splitter and the visible light from the illumination module, and outputting the received light to the reticle. The sensor is provided for detecting light energy of the secondary light beam at each wavelength. The controller is operably connected to the exposure module and the sensor, and configured to operate in a plurality of exposure modes according to which the controller turns on or off the UV-LED light sources of the exposure module. The controller is further configured to adjust an output of the UV-LED light sources of the exposure module based on a detected result of the sensor.

Preferably, the UV-LED light sources of the exposure module are directed to a G-line light source, a H-line light source, and an I-line light source that respectively emit radiation in wavelengths of about 436 nm, 405 nm and 365 nm; and the visible LED light source of the illumination module is directed to an E-line light source which emits radiation in wavelength of about 546 nm. In particular, the exposure modes of the controller at least includes a first exposure mode where only the G-line and H-line light sources are turned on, a second exposure mode where only the I-line light source is turned on, and a third exposure mode where all the G-line, H-line and I-line light sources are turned on. The controller can control a mixed ratio of the light generated by the UV-LED light sources of the exposure module.

The present invention allows a user to expose a photosensitive layer to UV radiation at one or more wavelengths as desired by controlling the UV-LED light sources of the exposure module with the controller. In addition, the amount of the light energy to be exposed on the photosensitive layer can be precisely given by adjusting the output power of the UV-LED light sources which is based on a detected result of the sensor. Moreover, the present invention allows a user to adjust a mixed ratio of the UV light generated by the UV-LED light sources to create a prescription for a particular photosensitive ingredient.

The foregoing and other objectives, features, and advantages of the invention will be more readily understood upon consideration of the following detailed description of the invention, taken in conjunction with the accompanying drawings.

### BRIEF DESCRIPTION OF THE DRAWINGS

FIG. 1 is a schematic diagram of a LED-based ultraviolet illuminator in accordance with one embodiment of the present invention; and

FIG. 2 is a schematic diagram of a LED-based ultraviolet illuminator in accordance with another embodiment of the present invention.

### DETAILED DESCRIPTION OF EMBODIMENTS

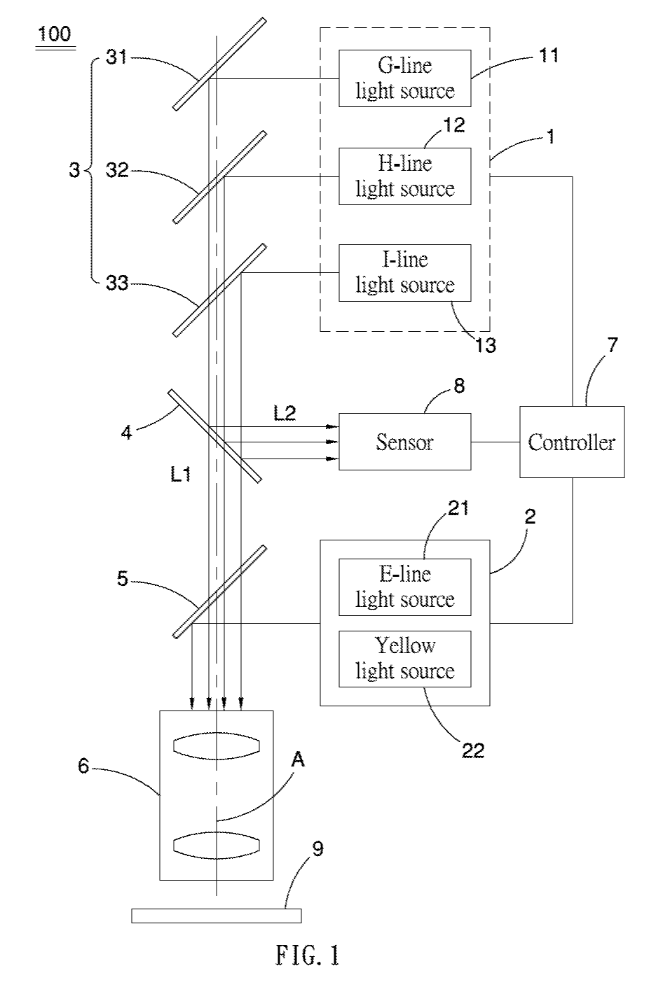

Referring to FIG. 1, there is shown one embodiment of the LED-based ultraviolet illuminator 100, which generally includes an exposure module 1 and an illumination module 2. The exposure module 1 includes a plurality of UV-LED light sources that emit UV light at different wavelengths for activating a photosensitive layer (not shown). The UV-LED light sources of the exposure module 1 are directed to at least two light sources selected from a group consisting of a G-line light source 11, a H-line light source 12, an I-line light source 13, a KrF light source (not shown) and a ArF light source (not shown) that respectively emit radiation in wavelengths of about 436 nm, 405 nm, 365 nm, 248 nm and 193 nm. In this embodiment, The exposure module 1 includes a combination of the G-line light source 11, the H-line light source 12, and the I-line light source 13. The light sources 11˜13 may be made of LED chips formed on patterned sapphire substrates (PSS). As known in the art, patterned substrates enhance LED light extraction, as compared to LED chips formed on conventional non-patterned sapphire substrates (CSS).

The illumination module 2 includes at least one visible LED light source that emits visible light for alignment of a reticle 9 (or patterned mask) with the photosensitive layer on a substrate (not shown), such as a PCB or wafer. In this embodiment, the illumination module 2 includes an E-line light source 21, and a yellow light source 22 that respectively emit radiation in wavelengths of about 546 nm and 578 nm.

As shown in FIG. 1, the LED-based ultraviolet illuminator 100 further includes a light mixing system 3, a beam splitter 4, a dichroic mirror 5, an optical lens system 6, a controller 7 and a sensor 8. The light mixing system 3 includes three dichroic mirrors 31˜33 corresponding to the G-line, H-line and I-line light sources 11˜13 such that the light mixing system 3 can receive the three UV light beams of the different wavelengths from the G-line, H-line and I-line light sources 11˜13, and combine the same into a mixed light beam along an optical path A. The beam splitter 4 is disposed in the optical path A for dividing the mixed light beam into a primary light beam L1 and a secondary light beam L2. It is understood that after the mixed light beam is split into the primary and secondary light beams L1, L2 in a desired mixing ratio by the beam splitter 4, each of the primary and secondary light beam L1 or L2 remains containing a portion of the UV light with all the different wavelengths, and no specific-wavelength light is filtered out by the beam splitter 4. The secondary light beam L2 is then received by the sensor 8 which is configured to detect the light energy of the secondary light beam L2 at each wavelength.

Among the beam splitter 4, the optical lens system 6, and the illumination module 2 is the dichroic mirror 5 which has one side for reflecting the visible light generated by the illumination module 2 to the optical lens system 6, and the other side allowing passage of the primary light beam L1 from the beam splitter 4 to the optical lens system 6. The optical lens system 6 is arranged on the optical path A for receiving both the primary light beam L1 from the beam splitter 4 and the visible light from the illumination module 2, and finally outputting the received light to the reticle 9 for further proceeding.

The controller 7 is operably connected to the exposure module 1 and is operable in a plurality of exposure modes. According to a selected one of the exposure modes, the controller 7 turns on or off the UV-LED light sources 11˜13 of the exposure module 1. The exposure modes of the controller 7 at least includes a first exposure mode where only the G-line and H-line light sources 11, 12 are turned on; a second exposure mode where only the I-line light source 13 is turned on; and a third exposure mode where all the G-line, H-line and I-line light sources 11˜13 are turned on. In this manner, one can choose a suitable exposure mode for a particular photosensitive ingredient (photoresist). On the other hand, the controller 7 is further coupled to the illumination module 2 and is operable in a plurality of illumination modes which includes at least a first illumination mode where only the E-line light source 21 is turned on; a second illumination mode where only the yellow light source 22 is turned on; and a third illumination mode where all the E-line and yellow light sources 21, 22 are turned on. The controller 7 is configured to turn on or off the E-line light source 21 and the yellow light source 22 according to a selected one of the illumination modes. One can choose one of the illumination modes to get a better illumination for alignment, as desired. As illustrated above, the controller 7 controls not only the UV-LED light sources 11˜13 of the exposure module 1 for activating a photosensitive layer, but also the visible LED light sources 21, 22 of the illumination module 2 for alignment.

Moreover, the controller 7 is operably connected to the sensor 8 and configured to adjust an output power (mW/cm²) of the UV-LED light sources 11-13 of the exposure module 1 based on a detected result of the sensor 8. For instance, the sensor 8 detects the light energy outputted from each of the G-line, H-line and I-line light sources 11˜13, and the controller 7 respectively adjusts the output power (mW/cm²) of the UV light generated by the UV-LED light sources 11˜13 of the exposure module 1 based on the detected result of the sensor 8 to ensure that the output power meets a manufacturing performance criteria. Besides, the controller 7 can further control a mixed ratio of the UV light generated by the UV-LED light sources 11˜13 of the exposure module 1. For instance, in the first exposure mode, one may use the controller 7 to control the G-line light source 11 and the H-line light source 12 to operate in a higher or lower electric power for adjustment of the output power of the light sources 11, 12 in order to meet the requirement of a particular photosensitive layer. This enables a precise mixed light to be obtained suitable for a particular photosensitive ingredient. Likewise, to provide an appropriate lighting for alignment, the controller 7 can also control the visible LED light sources 21, 22 of the illumination module 2 to operate in a higher or lower electric power for adjustment the output power of the light sources 21, 22.

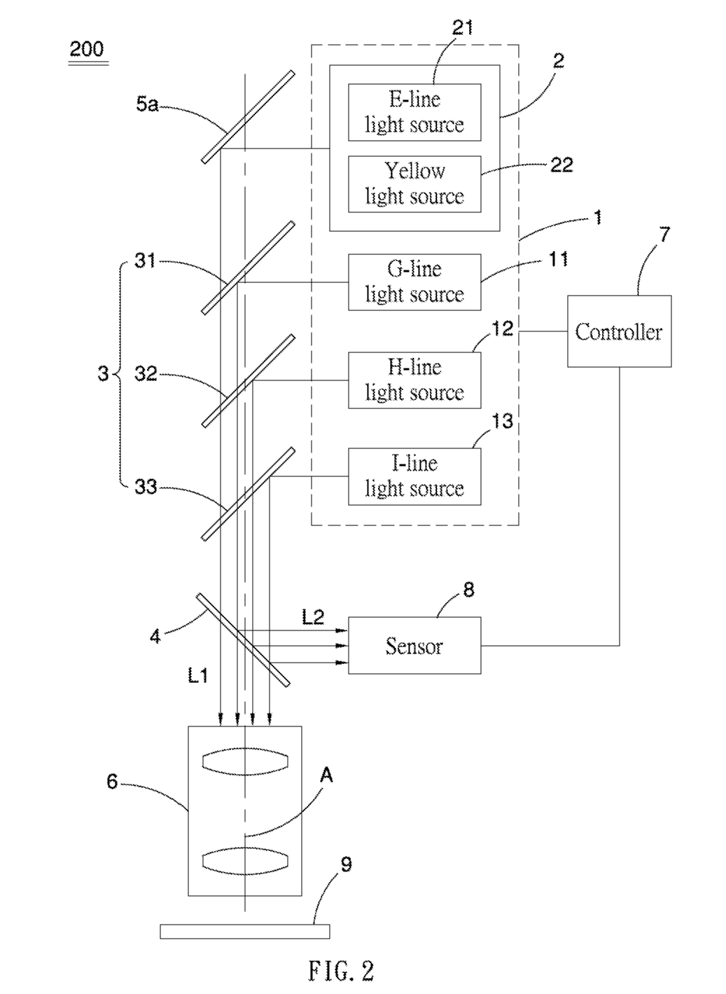

Referring to FIG. 2, a LED-based ultraviolet illuminator 200 in accordance with another embodiment will now be explained. Here, the illuminator 200 is substantially the same as that previously described illuminator 100 in FIG. 1, except that here the exposure module 1 and the illumination module 2 are integrated together in an assembly while the illumination module 2 is separated from the exposure module 1 in the previously described illuminator 100, and that a mirror 5a is employed in between the illumination module 2 and the light mixing system 3 for reflecting the visible light coming from the illumination module 2 to the light mixing system 3 such that the visible light is added in the mixed light beam and that each of the primary light beam L1 and the secondary light beam L2 contains a portion of the visible light.

As described above, the present invention allows a user to expose a photosensitive layer to UV radiation at one or more wavelengths as desired by controlling the UV-LED light sources of the exposure module with the controller. In addition, the amount of the light energy to be exposed on the photosensitive layer can be precisely given by adjusting the output power of the UV-LED light sources which is based on a detected result of the sensor. Moreover, the present invention allows a user to adjust a mixed ratio of the UV light generated by the UV-LED light sources to create a prescription for a particular photosensitive ingredient.

It should be evident that this disclosure is by way of example and that various changes may be made by adding, modifying or eliminating details without departing from the fair scope of the teaching contained in this disclosure.

What is claimed is:

1. A LED-based ultraviolet illuminator, comprising:
an exposure module including a plurality of UV-LED light sources that emit UV light at different wavelengths for activating a photosensitive layer;
an illumination module including at least one visible LED light source that emits visible light for alignment of a reticle with the photosensitive layer;
a light mixing system for receiving the UV light of the different wavelengths from the exposure module, and combining the UV light into a mixed light beam;
a beam splitter for splitting the mixed light beam into a primary light beam and a secondary light beam, each of which contains a portion of the UV light with all the different wavelengths;
an optical lens system for receiving the primary light beam from the beam splitter and the visible light from the illumination module, and outputting the received light to the reticle;
a sensor for detecting light energy of the secondary light beam at each wavelength; and
a controller operably connected to the exposure module and the sensor, and configured to operate in a plurality of exposure modes according to which the controller turns on or off the UV-LED light sources of the exposure module, and further to adjust an output of the UV-LED light sources of the exposure module based on a detected result of the sensor.

2. The illuminator as recited in claim 1, wherein the UV-LED light sources of the exposure module are directed to at least two light sources selected from a group consisting of a G-line light source, a H-line light source, an I-line light source, a KrF light source and a ArF light source, which respectively emit radiation in wavelengths of about 436 nm, 405 nm, 365 nm, 248 nm and 193 nm.

3. The illuminator as recited in claim 1, wherein the UV-LED light sources of the exposure module are directed to a G-line light source, a H-line light source, and an I-line light source that respectively emit radiation in wavelengths of about 436 nm, 405 nm and 365 nm; and the exposure modes of the controller at least includes a first exposure mode where only the G-line and H-line light sources are turned on, a second exposure mode where only the I-line light source is turned on, and a third exposure mode where all the G-line, H-line and I-line light sources are turned on.

4. The illuminator as recited in claim 2, wherein the visible LED light sources of the illumination module is directed to an E-line light source which emits radiation in wavelength of about 546 nm.

5. The illuminator as recited in claim 3, wherein the visible LED light source of the illumination module is directed to an E-line light source which emits radiation in wavelength of about 546 nm.

6. The illuminator as recited in claim 1, wherein the controller is further configured to control a mixed ratio of the UV light generated by the UV-LED light sources of the exposure module.

7. The illuminator as recited in claim 1, further comprising including a dichroic mirror that is arranged among the beam splitter, the optical lens system, and the illumination module, and has one side for reflecting the visible light coming from the illumination module to the optical lens system, and the other side allowing passage of the primary light beam from the beam splitter to the optical lens system.

8. The illuminator as recited in claim 1, further comprising including a mirror for reflecting the visible light coming from the illumination module to the light mixing system such that the visible light is added in the mixed light beam and that each of the primary light beam and the secondary light beam contains a portion of the visible light.

9. The illuminator as recited in claim 2, wherein the at least one visible LED light source of the illumination module includes an E-line light source and a yellow light source that respectively emit radiation in wavelengths of about 546 nm and 578 nm; and the controller is coupled to the illumination module and configured to operate in a plurality of illumination modes which includes a first illumination mode where only the E-line light source is turned on, a second illumination mode where only the yellow light source is turned on; and a third illumination mode where all the E-line and yellow light sources are turned on; and the controller turns on or off the E-line light source and the yellow light source according to a selected one of the illumination modes.

10. The illuminator as recited in claim 3, wherein the at least one visible LED light source of the illumination module includes an E-line light source and a yellow light source that respectively emit radiation in wavelengths of about 546 nm and 578 nm; and the controller is coupled to the illumination module and configured to operate in a plurality of illumination modes which includes a first illumination mode where only the E-line light source is turned on, a second illumination mode where only the yellow light source is turned on; and a third illumination mode where all the E-line and yellow light sources are turned on; and the controller turns on or off the E-line light source and the yellow light source according to a selected one of the illumination modes.

11. The illuminator as recited in claim 1, wherein in one of the exposure modes, the controller controls the UV-LED light sources of the exposure module to operate in a higher or lower electric power for adjustment of output power of the UV-LED light sources.

12. The illuminator as recited in claim 1, wherein in one of the exposure modes, the controller controls the UV-LED light sources of the exposure module and the visible LED light source of the illumination module to operate in a higher or lower electric power for adjustment of output power of the UV-LED light sources and the visible LED light source.
